(19) United States
(12) Patent Application Publication
(10) Pub. No.: US 2026/0040762 A1
(43) Pub. Date: Feb. 5, 2026

(54) TRANSISTOR STRUCTURE, GATE DRIVING CIRCUIT AND DISPLAY PANEL

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN); Beijing BOE Technology Development Co., Ltd., Beijing (CN)

(72) Inventors: Kai YU, Beijing (CN); Yongliang ZHAO, Beijing (CN)

(21) Appl. No.: 18/995,577

(22) PCT Filed: May 27, 2024
(86) PCT No.: PCT/CN2024/095478

§ 371 Date: Jan. 16, 2025

(51) Int. Cl. H10K 59/121

(52) U.S. Cl. CPC H10K 59/1213

(57) ABSTRACT

Provided are a transistor structure, a gate driving circuit and a display panel. The transistor group included in the transistor structure includes at least two control parts, at least two first electrode parts and at least two second electrode parts; the second electrode part and the first electrode part are alternately arranged along a length direction of a channel, and an orthographic projection of the control part onto a base substrate of the transistor structure is located between orthographic projections of one of the second electrode parts and one of the first electrode parts that are adjacent to each other onto the base substrate; the at least two first electrode parts include a non-edge first electrode part, the non-edge first electrode part is located between two adjacent second electrode parts, the two adjacent second electrode parts include at least one non-edge second electrode part.

### TECHNICAL FIELD

The present disclosure relates to the field of the display technologies, in particular to a transistor structure, a gate driving circuit and a display panel.

### BACKGROUND

With the continuous development of display technology, the application fields of display products are becoming more and more extensive, and accordingly, more and more requirements are put forward for display products. In order to reduce the production cost, simplify the production process, and reduce the width of non-display region, the GOA (Gate On Array) technology are applied to more and more display products. The GOA technology refers to integrating gate driving circuits onto an array substrate to save conventional gate drive chips. When using the GOA technology to drive a display product, the gate driving circuit needs to have a strong driving capability to enhance its control ability. Therefore, some transistors in the gate driving circuit need to meet the higher output current and the better characteristic uniformity.

### SUMMARY

This disclosure is to provide a transistor structure, a gate driving circuit and a display panel.

In order to achieve the above objective, the present disclosure provides the following technical solutions.

In a first aspect, the present disclosure provides a transistor structure, including: at least one transistor group arranged along a width direction of a channel. The at least one transistor group includes: at least two control parts, at least two first electrode parts and at least two second electrode parts: the second electrode part and the first electrode part are alternately arranged along a length direction of the channel, and an orthographic projection of the control part onto a base substrate of the transistor structure is located between orthographic projections of one of the second electrode parts and one of the first electrode parts that are adjacent to each other onto the base substrate;
the at least two first electrode parts include a non-edge first electrode part, the non-edge first electrode part is located between two adjacent second electrode parts, the two adjacent second electrode parts include at least one non-edge second electrode part, and the non-edge second electrode part is located between two adjacent first electrode parts;
the non-edge first electrode part includes a main body portion and at least one protrusion portion, where the protrusion portion is located between the main body portion and the non-edge second electrode part, and along the width direction of the channel, a width of at least part of the protrusion portion is less than a width of the main body portion.

Optionally, the transistor group includes an active pattern, and an overlapping region is formed between an orthographic projection of the active pattern onto the base substrate and an orthographic projection of each of the at least two control parts onto the base substrate; and along the width direction of the channel, the width of at least part of the protrusion portion is less than a width of the overlapping region.

Optionally, along the width direction of the channel, the width of the main body portion is greater than or equal to the width of the overlapping region.

Optionally, the non-edge first electrode part includes at least two protrusion portions, a part of the protrusion portions is located on a first side of the main body portion, and another part of the protrusion portions is located on a second side of the main body portion, where the first side and the second side are opposite to each other along the length direction of the channel.

Optionally, at least two protrusion portions arranged along the width direction of the channel are arranged on a same side of the main body portion, and the sum of minimum widths of the at least two protrusion portions along the width direction of the channel is less than the width of the overlapping region.

Optionally, the transistor structure includes at least two transistor groups arranged along the width direction of the channel, in adjacent transistor groups, main body portions adjacent to each other along the width direction of the channel are coupled through a first connection part, and along the length direction of the channel, a width of the first connection part is greater than or equal to the width of the main body portion.

Optionally, along the length direction of the channel, the width of the first connection part is greater than or equal to the sum of the width of the main body portion and the width of the protrusion portion.

Optionally, the protrusion portion includes at least two sub-portions arranged in sequence along the length direction of the channel, and widths of adjacent sub-portions along the width direction of the channel are different from each other; and at least one sub-portion of the at least two sub-portions has a width along the width direction of the channel that is less than the width of the overlapping region.

Optionally, the at least two sub-portions include at least one first sub-portion, the first sub-portion has a first width along the width direction of the channel, and the first width gradually increases or decreases in a direction away from the main body portion.

Optionally, the at least two sub-portions include at least one second sub-portion, the second sub-portion has a second width along the width direction of the channel, the second width is equal to a minimum value of the first width, and the second sub-portion is coupled to one end of the first sub-portion having the minimum value of the first width.

Optionally, the at least two sub-portions include a first sub-portion and a second sub-portion: the first sub-portion is located between the second sub-portion and the main body portion, or the second sub-portion is located between the first sub-portion and the main body portion.

Optionally, a maximum value of the first width is less than or equal to the width of the overlapping region.

Optionally, the at least two sub-portions include a third sub-portion, a fourth sub-portion and a fifth sub-portion arranged in sequence along the length direction of the channel: along the width direction of the channel, a width of the third sub-portion and a width of the fifth sub-portion are both greater than a width of the fourth sub-portion, and the width of the fourth sub-portion is less than the width of the overlapping region.

Optionally, the width of the third sub-portion along the width direction of the channel is less than or equal to the width of the overlapping region; and/or, the width of the fifth sub-portion along the width direction of the channel is less than or equal to the width of the overlapping region.

Optionally, the width of the third sub-portion is equal to the width of the fifth sub-portion along the width direction of the channel.

Optionally, the fourth sub-portion includes at least two sub-patterns arranged at intervals along the width direction of the channel, and the sum of widths of the at least two sub-patterns along the width direction of the channel is less than the width of the overlapping region.

Optionally, the transistor structure includes at least two transistor groups arranged along the width direction of the channel: in adjacent transistor groups, second electrode parts that are adjacent along the width direction of the channel are coupled to each other through a second connection part, and control parts that are adjacent along the width direction of the channel are coupled to each other through a third connection part; and along the width direction of the channel, on one side of the at least two transistor groups, the at least two second electrode parts are coupled to each other, on the other side of the at least two transistor groups, the at least two first electrode parts are coupled to each other, and the at least two control parts are coupled to each other.

Optionally, the control part includes bottom gate patterns and top gate patterns, and the bottom gate patterns, the active pattern and the top gate patterns are arranged in sequence along a direction away from the base substrate; and along the width direction of the channel, adjacent bottom gate patterns are coupled to each other through a bottom gate connection part, and adjacent top gate patterns are coupled to each other through a top gate connection part.

Optionally, the at least two first electrode parts include an edge first electrode part, and the edge first electrode part is located at an outermost edge of the transistor structure along the length direction of the channel: the edge first electrode part includes an edge main body portion and at least one edge protrusion portion, where the edge protrusion portion is located between the edge main body portion and the non-edge second electrode part, and along the width direction of the channel, a width of at least part of the edge protrusion portion is less than a width of the edge main body portion.

In a second aspect, based on the above transistor structure, the present disclosure provides a gate driving circuit including a shift register unit, where the shift register unit includes the above transistor structure.

In a third aspect, based on the technical solution of the gate driving circuit mentioned above, the present disclosure provides a display panel, including the gate driving circuit mentioned above.

### BRIEF DESCRIPTION OF THE DRAWINGS

The accompanying drawings described herein are intended to provide further understanding of the present disclosure and form a part of the present disclosure. The illustrative embodiments and their descriptions of the present disclosure are used to explain the present disclosure and do not constitute undue limitations onto the present disclosure. In the accompanying drawings:

FIG. 1 is a schematic diagram of a transistor structure according to an embodiment of the present disclosure;

FIG. 2 is a schematic diagram of a layout of a control electrode in FIG. 1;

FIG. 3 is a schematic diagram of a layout of a first electrode in FIG. 1;

FIG. 4 is a schematic diagram of a layout of a control electrode, a first electrode and a second electrode in FIG. 1;

FIG. 5 is a schematic diagram of a layout of a second electrode in FIG. 1;

FIG. 6 is a schematic diagram of a transistor structure showing poor uniformity of characteristics according to an embodiment of the present disclosure;

FIG. 7 is a schematic diagram of an input current density according to an embodiment of the present disclosure;

FIG. 8 is a schematic diagram of another input current density according to an embodiment of the present disclosure;

FIG. 9 is a schematic cross-sectional view of a display product according to an embodiment of the present disclosure:

FIG. 10 is a schematic diagram of a second layout of the first electrode according to an embodiment of the present disclosure;

FIG. 11 is a schematic diagram of a third layout of the first electrode according to an embodiment of the present disclosure;

FIG. 12 is a schematic layout diagram of a protrusion portion according to an embodiment of the present disclosure;

FIG. 13 is a schematic diagram of a fourth layout of the first electrode according to an embodiment of the present disclosure;

FIG. 14 is another layout diagram of a protrusion portion according to an embodiment of the present disclosure;

FIG. 15 is a schematic diagram of a fifth layout of the first electrode according to an embodiment of the present disclosure;

FIG. 16 is another layout schematic diagram of a protrusion portion according to an embodiment of the present disclosure;

FIG. 17 is a schematic diagram of a characteristic curve in the case of poor uniformity of characteristics according to an embodiment of the present disclosure;

FIG. 18 is a schematic diagram of a characteristic curve in the case of good uniformity of characteristics according to an embodiment of the present disclosure;

FIG. 19 is a circuit schematic of a shift register unit according to an embodiment of the present disclosure;

FIG. 20 is another layout schematic diagram of a protrusion portion according to an embodiment of the present disclosure;

FIG. 21 is another layout schematic diagram of a protrusion portion according to an embodiment of the present disclosure;

FIG. 22 is a schematic diagram showing H binding principle when the H content is low according to an embodiment of the present disclosure; and

FIG. 23 is a schematic diagram showing H binding principle when the H content is increased according to an embodiment of the present disclosure.

### DETAILED DESCRIPTION

In order to further illustrate a transistor structure, a gate driving circuit and a display panel provided by embodiments of the present disclosure, a detailed description will be provided below in conjunction with the accompanying drawings of the specification.

An organic light-emitting diode (OLED) display product is taken as an example. The OLED display product may specifically include a low temperature poly-silicon (LTPS) OLED display product, and a low temperature polycrystalline oxide (LTPO) OLED display product, etc. In the OLED display product, a gate driving circuit needs to have a strong driving capability to improve its control ability. Therefore, some transistors in the gate driving circuit need to meet the requirements of a relatively large output current Ion and a relatively good characteristic uniformity, such as characteristic uniformity of a threshold voltage Vth.

For OLED display products, especially an OLED display product including an oxide transistor of a high mobility, due to the limitation of material mobility (usually Mob<30 cm2/V·S), in order to ensure the driving capability of the gate driving circuit, it is necessary to ensure the output capability of an output transistor (Buffer TFT) coupled to a driving signal output terminal, and the channel width of the Buffer TFT needs to be significantly increased. For example, the channel width to length ratio W/L of the Buffer TFT is 400/6, but not limited to this. In some cases, due to the limitation of layout space, in order to achieve a larger channel width, output transistors may be designed with multiple groups of TFT arranged in series. However, this method of significantly increasing the channel width of Buffer TFT has the problem of poor characteristic uniformity and severe negative bias in some positions, causing fluctuations in a threshold voltage Vth of the output transistor, which leads to a decrease in the display quality of the display product due to the signal outputted by the gate driving circuit.

Therefore, how to enable some transistors in a gate driving circuit to have a larger width to length ratio to meet the higher output current and better characteristic uniformity becomes a technical problem urgently to be solved.

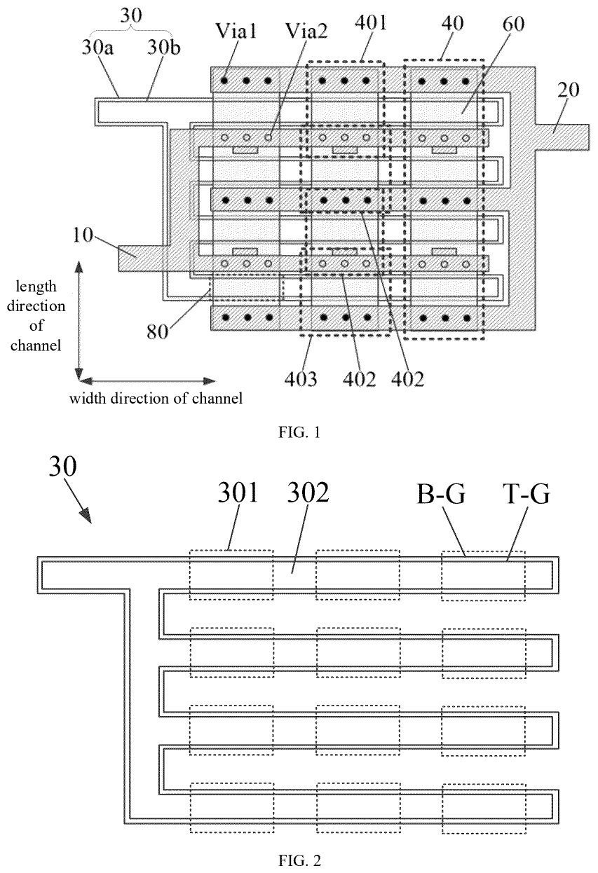

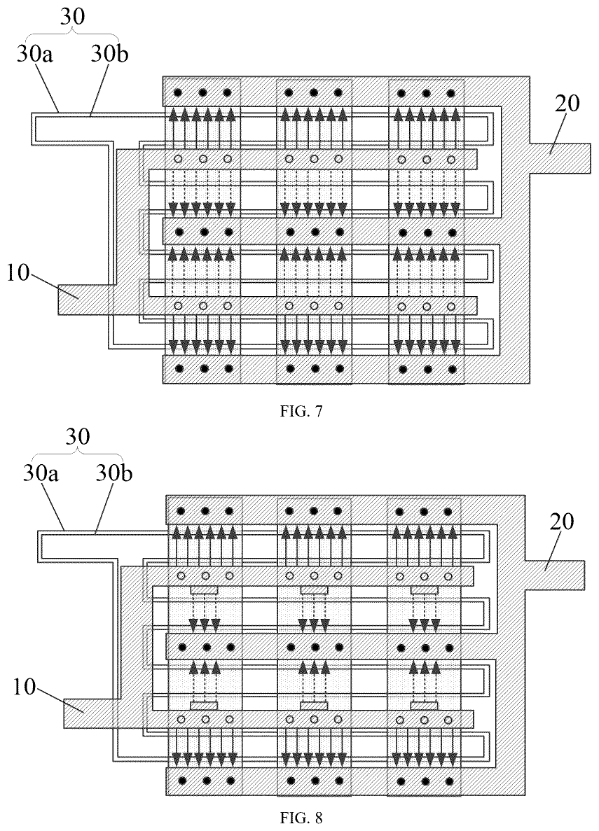

Referring to FIG. 1 to FIG. 5, FIG. 7 and FIG. 8. An embodiment of the present disclosure provides a transistor structure, including: at least one transistor groups 40 arranged along a width direction of a channel: at least one transistor groups 40 includes: at least two control parts 301, at least two first electrode parts 101 and at least two second electrode parts 201: the second electrode parts 201 and the first electrode parts 101 are alternately arranged along a length direction of a channel, and an orthographic projection of the control part 301 onto a base substrate of the transistor structure is located between orthographic projections of a second electrode part 201 and a first electrode part 101 onto the base substrate that are adjacent.

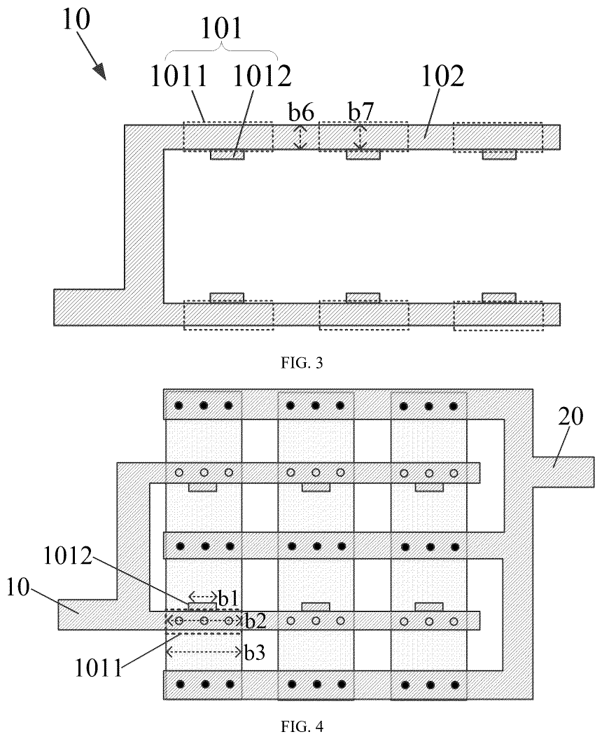

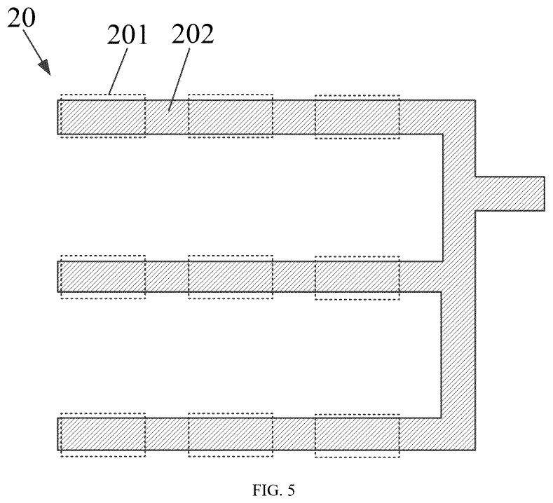

The at least two first electrode parts 101 include a non-edge first electrode part (for example, two first electrode parts 101 as shown in FIG. 3), and the non-edge first electrode part is located between two adjacent second electrode parts 201. The two adjacent second electrode parts 201 include at least one non-edge second electrode part (for example, second electrode part 201 located in the middle along the length direction of the channel as shown in FIG. 5), and the non-edge second electrode part is located between two adjacent first electrode parts 101. It is worth noting that the non-edge electrode part is not located at the outermost edge of the transistor structure along the length direction of the channel, that is, a second electrode part is arranged on a side of the non-edge electrode part facing the outermost edge.

As shown in FIG. 4, the non-edge first electrode part includes a main body portion 1011 and at least one protrusion portion 1012, the protrusion portion 1012 is located between the main body portion 1011 and the non-edge second electrode part, and along the width direction of the channel, a width b1 of at least part of the protrusion portion 1012 is less than a width b2 of the main body portion 1011.

Exemplarily, the transistor structure includes at least two transistor groups 40 arranged along the width direction of the channel.

For example, the transistor structure includes three groups of transistors 40 arranged along the width direction of the channel, but is not limited thereto. It should be noted that the width direction of the channel and the length direction of the channel correspond to the channel width to length ratio of the transistor structure, that is, a length of a channel of the transistor structure is a length of the channel in the length direction of the channel, and a width of the channel of the transistor structure is a width of the channel in the width direction of the channel.

Exemplarily, the control part 301 includes a gate part, the first electrode part 101 includes a source part, and the second electrode part 201 includes a drain part, which are not limited thereto.

For example, the second electrode part 201 and the first electrode part 101 are alternately arranged along the length direction of the channel. For example, the number of the second electrode parts 201 is one more than the number of the first electrode parts 101, or the number of the first electrode parts 101 is one more than the number of the second electrode parts 201. An example is given that at least one transistor group 40 includes four control parts 301, two first electrode parts 101, and three second electrode parts 201. Along the length direction of the channel, the first one of the second electrode parts 201, the first one of the first electrode parts 101, the second one of the second electrode parts 201, the second one of the first electrode parts 101, and the third one of the second electrode parts 201 are arranged in sequence. The four control parts 301 are arranged in sequence along the length direction of the channel, and an orthographic projection of the control part 301 onto the base substrate is located between orthographic projections of the first electrode part 101 and the second electrode part 201 that are adjacent to each other onto the base substrate.

For example, the at least two first electrode parts 101 include at least one non-edge first electrode part, and each non-edge first electrode part is located between two adjacent second electrode parts 201. That is, the non-edge first electrode part is not located at the outermost side of the transistor structure along the length direction of the channel. Whether the at least two first electrode parts 101 include an edge first electrode parts 101 or not may be configured as needed. The edge first electrode part 101 refer to a part located at the outermost side of the transistor structure along the length direction of the channel, that is, it is not located between two adjacent second electrode parts 201. For example, the non-edge first electrode parts include: a first one of the first electrode parts 101 and a second one of the first electrode parts 101.

For example, the two adjacent second electrode parts 201 include at least one non-edge second electrode part, and each non-edge second electrode part is located between the two adjacent first electrode parts 101. That is, the non-edge second electrode part is not located at the outermost side of the transistor structure along the length direction of the channel. For example, the non-edge second electrode part includes the second one of the second electrode parts 201.

For example, the non-edge first electrode part includes a main body portion 1011 and at least one protrusion portion 1012, and the main body portion 1011 and the protrusion portion 1012 are formed as an integrated structure.

For example, a first electrode part 101 and a second electrode part 201 that are adjacent to each other, and a control part 301 having an orthographic projection onto the base substrate located between orthographic projections of the first electrode part 101 and the second electrode part 201 onto the base substrate jointly form a sub-transistor in one transistor group 40 to which the first electrode part, the second electrode part and the third electrode part belong. It should be noted that one transistor group 40 includes multiple sub-transistors arranged along the length direction of the channel, and one of the first electrode parts 101 or one of the second electrode parts 201 may be shared by adjacent sub-transistors. The multiple sub-transistors include one starting sub-transistor 401, at least one middle sub-transistor 402, and one ending sub-transistor 403 arranged in sequence along the length direction of the channel. The starting sub-transistor 401 and the ending sub-transistor 403 are both located on the outermost sides of a transistor structure along the length direction of the channel, and the intermediate sub-transistor 402 is located in a middle region of the transistor structure along the length direction of the channel.

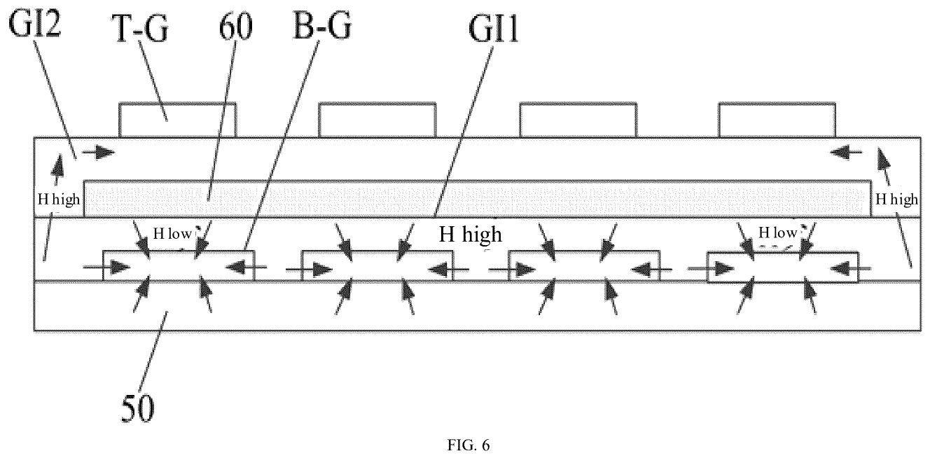

As shown in FIG. 6, the control part 301 (including a top gate pattern T-G and a bottom gate pattern B-G) is generally made of metal Mo (Molybdenum). An insulation layer (such as GI) between the control part 301 and the active layer 60 includes H (hydrogen). In a case where the buffer TFT is set to include the transistor structure, the density of Mo is relatively high, and Mo is a columnar grain and has the H (hydrogen) absorption effect. Therefore, the density of Mo may affect the H content around the active layer. The H near the edge of the active layer is prone to diffuse to the outermost side of the active layer, resulting in a lower H content near the edge of the active layer and a higher H content on the outermost side of the active layer. However, the H near the middle part of the active layer is difficult to diffuse, resulting in a higher content of H near the middle part of the active layer, causing a characteristic shift in the transistor structure and causing the intermediate sub-transistor 402 in the transistor structure to be turned on earlier. It should be noted that a direction of an arrow in FIG. 6 represents a diffusion direction of H and a direction of H absorbed by Mo.

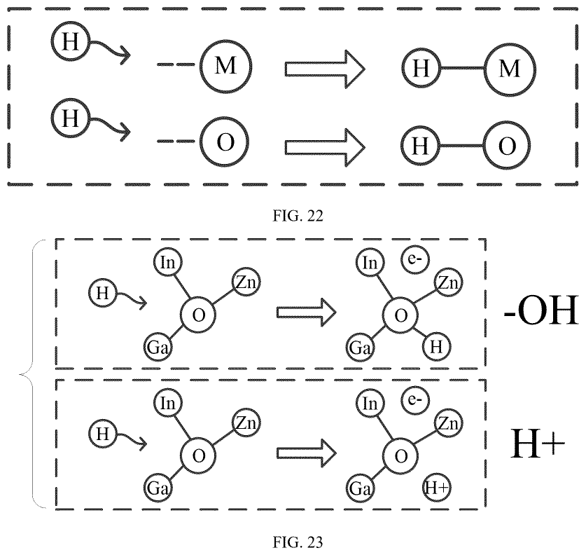

More specifically, as shown in FIG. 22, when the H content is relatively low, the H mainly combines with metal bonds (M) or oxygen bonds (O) to passivate defects, resulting in a decrease in carrier concentration and a positive shift in Vth. As shown in FIG. 23, with the increase of H content, as a donor defect, —OH bonds or H+ are formed, resulting in an increase in the carrier concentration, and a negative shift in Vth. It should be noted that FIG. 23 illustrates the binding between H and indium gallium zinc oxide (IGZO) as the H content increases.

Based on the above principle, as shown in FIG. 23, the intermediate sub-transistor 402 has a high H content near the active layer, which causes a characteristic shift in the transistor structure and causes the transistor structure to be turned on earlier than planned or expected.

According to the specific structure of the transistor structure described above, it may be seen that in the transistor structure according to the embodiments of the present disclosure, the non-edge first electrode part includes the main body portion 1011 and at least one protrusion portion 1012, the protrusion portion 1012 is located between the main body portion 1011 and the non-edge second electrode part, so that the non-edge first electrode part, the non-edge second electrode part, and a control part 301 having an orthographic projection onto the base substrate located between orthographic projections of the non-edge first electrode part and the non-edge second electrode part onto the base substrate can jointly form an intermediate transistor 402. A width of at least part of the protrusion portion 1012 is less than a width of the main body portion 1011, which enables a width of the non-edge first electrode part to be narrowed in a direction close to a channel region of the intermediate sub-transistor 402. In this way, the concentration of transport carriers in the intermediate sub-transistor 402 during operation can be effectively reduced, which reduces the input current density of the intermediate sub-transistor 402 and better balances the overall current density of the transistor structure, thereby effectively overcoming the problem that the intermediate sub-transistor 402 is turned on early due to the characteristic deviation of the transistor structure, and greatly improving the characteristic uniformity of the transistor structure.

Therefore, when applying the transistor structure according to the embodiments of the present disclosure to a gate driving circuit, it is able to achieve a strong driving capability of the gate driving circuit, thereby greatly improving the control capability of the gate driving circuit and ensuring the display effect of the display product under the driving of the gate driving circuit.

It should be noted that, as shown in FIG. 7 and FIG. 8, the solid arrow represent the input current density of a sub-transistor in the outermost side, and the dashed arrow represent the input current density of the intermediate sub-transistor 402.

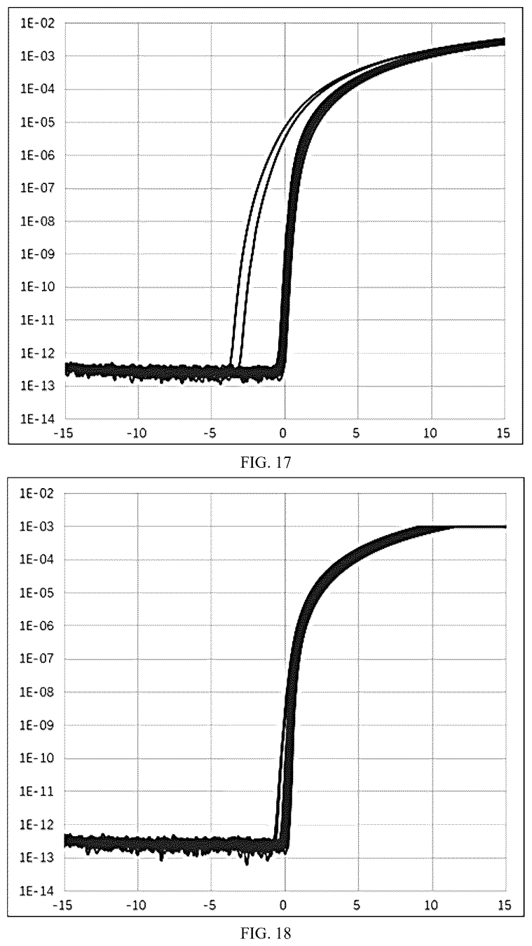

For example, the fluctuation parameter 38 for evaluating the threshold voltage of the transistor structure may be improved from 1.6 to 0.5. Specifically, as shown in FIG. 17 and FIG. 18, FIG. 17 illustrates the Id-Vg curve in the related art, and FIG. 18 illustrates the Id-Vg curve in the embodiments of the present disclosure. The horizontal axis in the two figures represents Vg, with the unit of V, and the vertical axis represents Id, with the unit of A. Vg represents a voltage of the control part 301 of the transistor structure, and Id represents a current of the drain electrode of the transistor structure.

As shown in FIG. 1 and FIG. 4, in some embodiments, the transistor group 40 includes an active pattern 60, and an overlapping region 80 is formed between an orthographic projection of the active pattern 60 onto the base substrate and an orthographic projection of each of the at least two control parts 301 onto the base substrate; and along the width direction of the channel, the width of at least part of the protrusion portion 1012 is less than a width of the overlapping region 80.

Illustratively, the active pattern 60 extends along the length direction of the channel, but is not limited to this.

Illustratively, overlapping regions 80 are formed between the orthographic projection of the active pattern 60 onto the base substrate and orthographic projections of the at least two control parts 301 onto the base substrate, respectively. A portion of the active pattern 60 located in the overlapping region 80 is a channel portion of each sub-transistor.

In the above arrangement, the width of at least part of the protrusion portion 1012 is less than the width of the overlapping region 80, which enable the width of the non-edge first electrode part to become narrowed along a direction close to the channel portion of the intermediate sub-transistor 402 to which the non-edge first electrode part belongs. In this way, the input current density of the intermediate sub-transistor 402 during operation can be effectively reduced, to achieve the effect of balancing the overall current density of the transistor structure, thereby effectively overcoming the problem that the intermediate sub-transistor 402 is turned on early due to the characteristic deviation of the transistor structure, and greatly improving the characteristic uniformity of the transistor structure.

As shown in FIG. 4, in some embodiments, along the width direction of the channel, the width b2 of the main body portion 1011 is greater than or equal to the width b3 of the overlapping region 80.

In the above arrangement, it can ensure that a current can be well transmitted through the main body portion 1011 having a relatively large area when the current flows through the main body portion 1011, thereby ensuring the transmission performance of the non-edge first electrode part included in the intermediate sub-transistor 402 while reducing the input current density of the intermediate sub-transistor 402.

As shown in FIG. 20, in some embodiments, the non-edge first electrode part includes at least two protrusion portions 1012, a part of the protrusion portions 1012 is located on a first side of the main body portion 1011, and another part of the protrusion portions 1012 is located on a second side of the main body portion 1011, where the first side and the second side are opposite to each other along the length direction of the channel.

Illustratively, a part of the protrusion portion 1012 is located on a first side of the main body portion 1011, and a sub-transistor is formed by a non-edge first electrode part, a control part 301 and a non-edge second electrode part that are adjacent to the first side of the non-edge first electrode part: another part of the protrusion portion 1012 is located on a second side of the main body portion 1011, and another sub-transistor is formed by the non-edge first electrode part, a control part 301 and a non-edge second electrode part that are adjacent to the second side of the non-edge first electrode part. The non-edge first electrode part is shared by the two sub-transistors.

In the above arrangement, it is conducive to further reducing the input current density of the intermediate sub-transistor 402, and to achieving the effect of balancing the overall current density of the transistor structure, thus effectively overcoming the problem of early turn-on of the intermediate sub-transistor 402 caused by the deviation of characteristics of the transistor structure, and greatly improving the uniformity of characteristics of the transistor structure.

Moreover, in the above arrangement, the input current density of the intermediate sub-transistor 402 is reduced without increasing the complexity of the transistor structure, which is conducive to simplifying the layout space occupied by the transistor structure and reducing the layout difficulty of the transistor structure in a limited layout space.

As shown in FIG. 21, in some embodiments, at least two protrusion portions 1012 arranged along the width direction of the channel are arranged on a same side of the main body portion 1011, and the sum (for example, b4+b5) of minimum widths of the at least two protrusion portions 1012 along the width direction of the channel is less than the width of the overlapping region 80.

In the above arrangement, at least two protrusion portions 1012 are arranged on the same side of the main body portion 1011 and arranged along the width direction of the channel, which enables the input current to be distributed more uniformly and is beneficial for improving the stability of characteristics of the sub-transistor.

In the above arrangement, the sum of the minimum widths of the at least two protrusion portions 1012 along the width direction of the channel is less than the width of the overlapping region 80, which can effectively reduce the input current density of the intermediate sub-transistor 402, thereby effectively overcoming the problem that the intermediate sub-transistor 402 is turned on early due to the characteristic deviation of the transistor structure, and significantly improving the characteristic uniformity of the transistor structure.

As shown in FIG. 3, in some embodiments, the transistor structure includes at least two transistor groups arranged along a width direction of a channel. In adjacent transistor groups 40, main body portions 1011 adjacent to each other along the width direction of the channel are coupled through a first connection part 102. Along the length direction of the channel, a width b6 of the first connection part 102 is greater than or equal to the width b7 of the main body portion 1011.

For example, along the length direction of the channel, the width of the first connection part 102 is greater than or equal to the sum of widths of the main body portion 1011 and the protrusion portion 1012.

For example, the first connection part 102 and the main body portion 1011 coupled to the first connection part 102 are formed as an integrated structure.

As shown in FIG. 2 and FIG. 5, the transistor structure includes at least two transistor groups arranged along the width direction of the channel. In adjacent transistor groups 40, second electrode parts 201 that are adjacent along the width direction of the channel are coupled to each other through a second connection part 202, and control parts 301 that are adjacent along the width direction of the channel are coupled to each other through a third connection part 302. As shown in FIG. 1, along the width direction of the channel, on one side of the at least two transistor groups 40, the multiple second electrode parts 201 are coupled to each other, on the other side of the at least two transistor groups 40, the multiple first electrode parts 101 are coupled to each other, and the multiple control parts 301 are coupled to each other.

For example, on one side of at least two transistor groups 40 along the width direction of the channel, the multiple second electrode parts 201 are coupled to each other, achieving the connection of all the second electrode parts 201 included in the transistor structure to form the second electrode 20 of the transistor structure.

For example, on the other side of at least two transistor groups 40 along the width direction of the channel, the multiple first electrode parts 101 are coupled to each other, achieving the connection of all the first electrode parts 101 included in the transistor structure to form the first electrode 10 of the transistor structure.

For example, on the other side of at least two transistor groups 40 along the width direction of the channel, the multiple control parts 301 are coupled to each other, achieving the connection of all the control parts 301 included in the transistor structure to form the control electrode 30 of the transistor structure. The control electrode 30 may include a first control layer 30a and a second control layer 30b. The first control layer 30a includes the bottom gate pattern B-G, and the second control layer 30B includes the top gate pattern T-G.

When the transistor structure is connected to the shift register unit, the transistor structure may be coupled to other structures in the shift register unit through the first electrode, the second electrode, and the control electrode 30.

In the above arrangement, the width of the first connection part 102 along the length direction of the channel is greater than or equal to the width of the main body portion 1011, and the width of the first connection part 102 along the length direction of the channel is greater than or equal to the sum of the widths of the main body portion 1011 and the protrusion portion 1012, which ensures a current to be well transmitted by the first connection part 102 having a larger area when the current flows through the first connection part 102, thereby reducing the input current density of the intermediate sub-transistor 402 and ensuring the transmission performance of the current between adjacent main body portions 1011.

In the above arrangement, the transistor structure includes at least two transistor groups 40 arranged in series along the width direction of the channel, ensuring that the transistor structure has a larger channel width to length ratio.

As shown in FIG. 1 to FIG. 5, in some embodiments, the control part 301 includes bottom gate patterns B-G and top gate patterns T-G. Along a direction away from the base substrate, the bottom gate pattern B-G, the active pattern 60, and the top gate pattern T-G are arranged in sequence: along the width direction of the channel, adjacent bottom gate patterns B-G are coupled to each other through a bottom gate connection part, and adjacent top gate patterns T-G are coupled to each other through a top gate connection part.

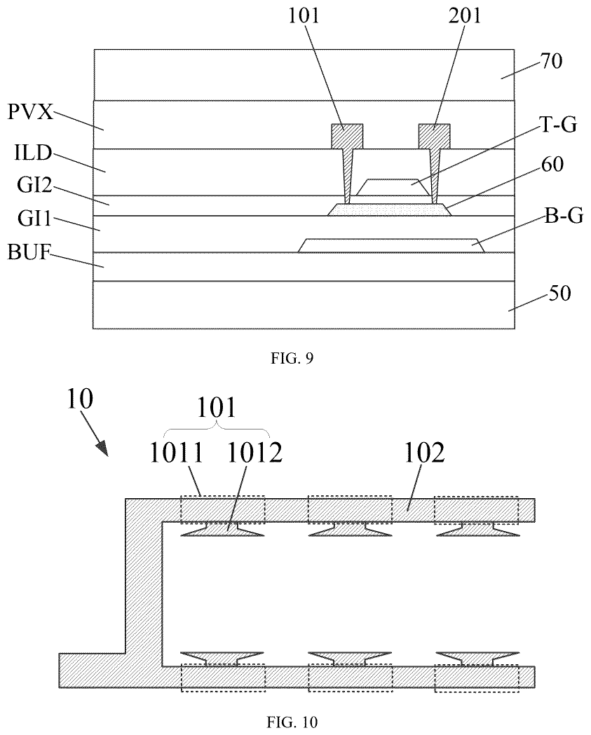

As shown in FIG. 9, for example, a buffer layer BUF with a thickness of 100 nm is formed on the base substrate 50 by using the material of SiOx and the plasma enhanced chemical vapor deposition (PECVD) method at 380° C., and the buffer layer BUF is used as an insulation dielectric layer: a molybdenum material layer with thickness of 300 nm is further deposited by using the Sputter magnetron sputtering technique, and the molybdenum material layer is patterned by using the patterning processes such as exposure, development and etching, to form bottom gate patterns B-G and bottom gate connection parts. Then, a first insulation layer GI1 with a thickness of 300 nm is formed by using the material of SiOx and the PECVD method at 380° C.: an indium gallium oxide (IGO) thin film with a thickness of 25 nm is deposited at room temperature by using the target material of Indium gallium oxide (In2O3:Ga2O3=1:1 wt %) and the Sputter magnetron sputtering technique, and the IGO thin film is patterned to form an active pattern 60; a second insulation layer GI2 is formed by PECVD by using the material of SiOx: a molybdenum material layer with thickness of 300 nm is deposited by using a Sputter sputtering film-forming device, and the molybdenum material layer is patterned by using the patterning processes such as exposure, development and etching, to form top gate patterns T-G and top gate connection parts. Subsequently, an interlayer insulation layer (ILD) is formed: a source drain metal layer with a thickness of 700 nm is formed by using the Sputter magnetron sputtering technique, the source drain metal layer includes Ti, Al and Ti thin films stacked in sequence, and the source drain metal layer is patterned through the patterning process to form the first electrode part 101 and the second electrode part 201. The first electrode part 101 and the second electrode part 201 are coupled to corresponding parts of the active pattern 60 (coupling may be achieved through via holes Via1 and Via2 as shown in FIG. 1), and are used as the source electrode and the drain electrode of the transistor structure. FIG. 9 also illustrates a passivation layer PVX and a multi-film layer 70. The multi-film layer 70 may include a planarization layer, a second source drain metal layer, an anode layer, and a pixel defining layer, but is not limited thereto.

In the transistor structure provided in the above embodiments, the transistor structure is formed as a dual-gate structure including top gate patterns T-G and bottom gate patterns B-G. Of course, the transistor structure may also be formed as a single-gate structure that only includes top gate patterns T-G or bottom gate patterns B-G.

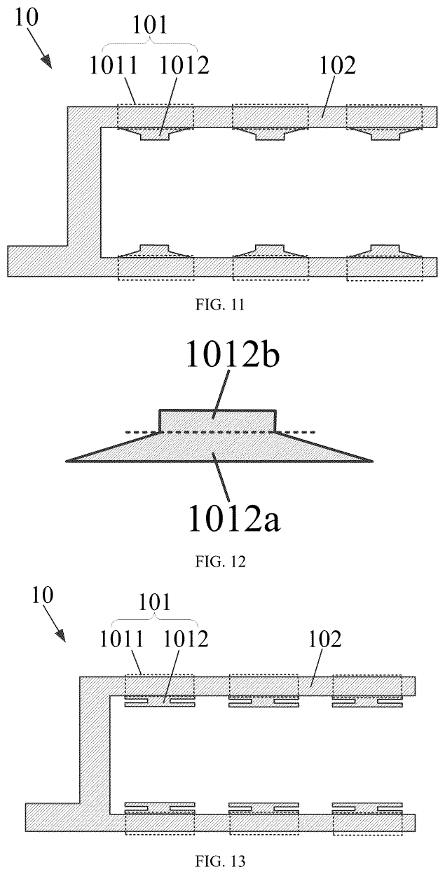

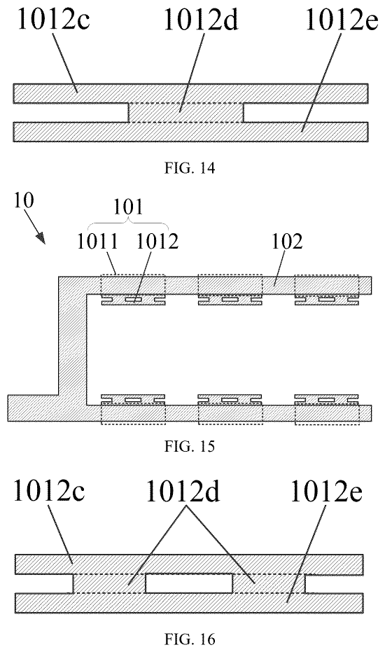

As shown in FIG. 10 to FIG. 16, in some embodiments, the protrusion portion 1012 includes at least two sub-portions arranged in sequence along the length direction of the channel (such as a first sub-portion 1012a, a second sub-portion 1012b, a third sub-portion 1012c, a fourth sub-portion 1012d, and a fifth sub-portion 1012e), and adjacent sub-portions have different widths along the width direction of the channel: at least one sub-portion of the at least two sub-portions has a width along the width direction of the channel that is less than the width of the overlapping region 80.

For example, the protrusion 1012 includes at least two sub-portions arranged in sequence along the length direction of the channel, which are formed as an integrated structure.

By setting adjacent sub-portions having different widths along the width direction of the channel, the protrusion portion 1012 of the first electrode part 101 can be narrowed by different widths at different positions, thereby achieving better adjustment of the current density.

By setting at least one sub-portion of the two sub-portions to have a width along the width direction of the channel that is less than the width of the overlapping region 80, the input current density of the intermediate sub-transistor 402 can be effectively reduced, so as to achieve the effect of balancing the overall current density of the transistor structure, thereby effectively overcoming the problem that the intermediate sub-transistor 402 is turned on early due to the characteristic deviation of the transistor structure, and greatly improving the characteristic uniformity of the transistor structure.

As shown in FIG. 10 to FIG. 12, in some embodiments, the at least two sub-portions include at least one first sub-portion 1012a, the first sub-portion 1012a has a first width along the width direction of the channel, and the first width gradually increases or decreases in a direction away from the main body portion 1011.

For example, the first sub-portion 1012a is formed to be a regular trapezoid structure or an inverted trapezoid structure, but not limited to this.

In the above arrangement, the protrusion portion 1012 of the first electrode part 101 may be narrowed by different widths at different positions, thereby achieving better adjustment of the current density. Moreover, by designing that the first width of the first sub-portion 1012a along the width direction of the channel gradually increases or decreases in the direction away from the main body portion 1011, it is able to better achieve the adjustment from the high current density to the low current density while adjusting the current density.

As shown in FIG. 10 to FIG. 12, in some embodiments, the at least two sub-portions include at least one second sub-portion 1012b, the sub-portion 1012b has a second width along the width direction of the channel, and the second width is equal to a minimum value of the first width. The second sub-portion 1012b is coupled to one end of the first sub-portion 1012a with the minimum first width.

For example, the at least two sub-portions include one first sub-portion 1012a and one second sub-portion 1012b. The first sub-portion 1012a is located between the second sub-portion 1012b and the main body portion 1011, or the second sub-portion 1012b is located between the first sub-portion 1012a and the main body portion 1011.

In the above arrangement, the protrusion portion 1012 of the first electrode part 101 can be narrowed by different widths at different positions, thereby achieving better adjustment of the current density. Moreover, at least one second sub-portion 1012b includes at least two sub-portions, which is advantageous for achieving low current density.

In some embodiments, a maximum value of the first width is set to be less than or equal to the width of the overlapping region 80. In this setting manner, the input current density of the intermediate sub-transistor 402 can be effectively reduced, and the effect of balancing the overall current density of the transistor structure can be achieved, thus effectively overcoming the problem of early turn-on of the intermediate sub-transistor 402 caused by the deviation of characteristics of the transistor structure, and greatly improving the uniformity of characteristics of the transistor structure.

As shown in FIG. 13 to FIG. 16, in some embodiments, the at least two sub-portions include: a third sub-portion 1012c, a fourth sub-portion 1012d, and a fifth sub-portion 1012e arranged in sequence along the length direction of the channel: along the width direction of the channel, a width of the third sub-portion 1012c and a width of the fifth sub-portion 1012e are both greater than a width of the fourth sub-portion 1012d, and the width of the fourth sub-portion 1012d is less than the width of the overlapping region 80.

For example, the width of the third sub-portion 1012c along the width direction of the channel is less than or equal to the width of the overlapping region 80; and/or, the width of the fifth sub-portion 1012e along the width direction of the channel is less than or equal to the width of the overlapping region 80.

For example, along the width direction of the channel, the width of the third sub-portion 1012c is equal to the width of the fifth sub-portion 1012e.

By setting the width of the third sub-portion 1012c and the width of the fifth sub-portion 1012e to be greater than the width of the fourth sub-portion 1012d, and the width of the fourth sub-portion 1012d to be less than the width of the overlapping region 80, the protrusion portion 1012 of the first electrode part 101 can be narrowed by different widths at different positions, thereby achieving better adjustment of the current density.

By setting the width of the fourth sub section 1012d to be less than the width of the overlapping region 80, the input current density of the intermediate sub-transistor 402 can be effectively reduced, so as to achieve the effect of balancing the overall current density of the transistor structure, thereby effectively overcoming the problem that the intermediate sub-transistor 402 is turned on early due to the characteristic deviation of the transistor structure, and greatly improving the characteristic uniformity of the transistor structure.

In some embodiments, the fourth sub-portion 1012d includes at least two sub-patterns arranged at intervals along the width direction of the channel, and the sum of the widths of the at least two sub-patterns along the width direction of the channel is less than the width of the overlapping region 80.

The above setting method can effectively reduce the input current density of the intermediate sub-transistor 402, to achieve the effect of balancing the overall current density of the transistor structure, thereby effectively overcoming the problem that the intermediate sub-transistor 402 is turned on early due to the characteristic shift of the transistor structure, and greatly improving the characteristic uniformity of the transistor structure. Furthermore, the protrusion portion 1012 of the first electrode part 101 can be narrowed by different widths at different positions, thereby achieving better adjustment of the current density.

In some embodiments, the at least two first electrode parts include an edge first electrode part, and the edge first electrode part is located at the outermost edge of the transistor structure along the length direction of the channel.

The edge first electrode part includes an edge main body portion and at least one edge protrusion portion, the edge protrusion portion is located between the edge main body portion and the non-edge second electrode part, and a width of at least part of the edge protrusion portion is less than a width of the edge main body portion along the width direction of the channel.

For example, the at least two first electrode parts include an edge first electrode part, and the edge first electrode part is located at the outermost side of the transistor structure along the length direction of the channel.

For example, the edge protrusion portion is located between the edge main body portion and the non-edge second electrode part, and the non-edge second electrode part is located between two adjacent first electrode parts 101. That is, the edge protrusion portion is located on a side of the edge main body portion facing the inside of the transistor structure.

The above setting method can adjust the turn-on time of the edge sub-transistor, which is beneficial for improving the characteristic uniformity of the transistor structure. Moreover, the above setting method is conducive to reducing the overall layout space occupied by the transistor structure and lowering the layout difficulty of the transistor structure.

An embodiment of the present disclosure further provides a gate driving circuit, including a shift register unit. The shift register unit includes the transistor structure provided in the above embodiments.

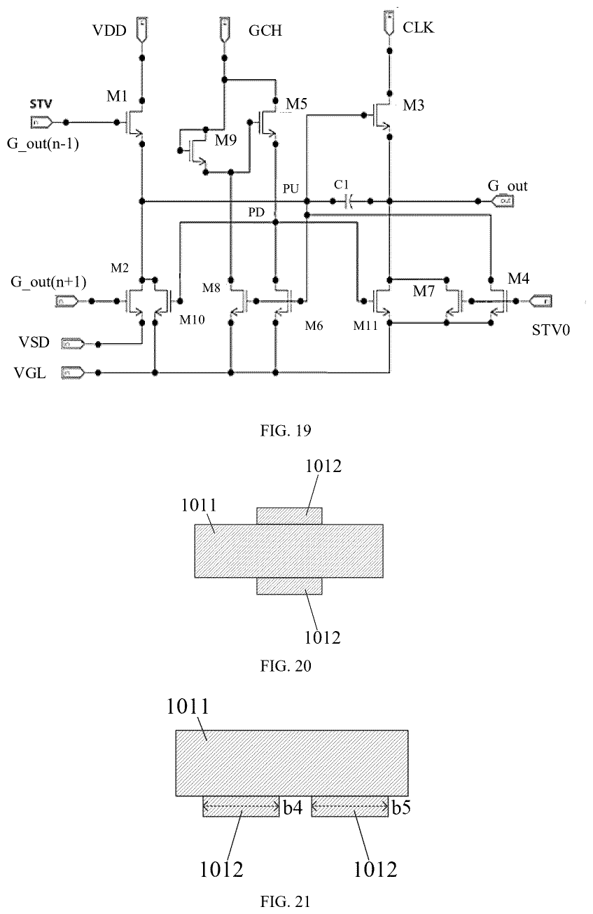

As shown in FIG. 19, a circuit structure of the shift register unit included in the gate driving circuit is illustrated, but not limited to this.

The shift register unit includes:
a first transistor M1, where a gate electrode of the first transistor M1 is coupled to a frame start signal input terminal STV or an output terminal G_out(n−1) of an upper stage of shift register unit cascaded to the current gate driving circuit, a first electrode of the first transistor M1 is coupled to a power signal input terminal VDD, and a second electrode of the first transistor M1 is coupled to a pull-up node PU;
a second transistor M2, where a gate electrode of the second transistor M2 is coupled to an output terminal G_out(n+1) of a next stage of shift register unit cascaded to the current gate driving circuit, a first electrode of the second transistor M2 is coupled to a second level signal input terminal VSD, and a second electrode of the second transistor M2 is coupled to a pull-up node PU;
a third transistor M3, where a gate electrode of the third transistor M3 is coupled to the pull-up node PU, a first electrode of the third transistor M3 is coupled to a clock signal, and a second electrode of the third transistor M3 is coupled to an output terminal G_out of the shift register unit to which it belongs;
a fourth transistor M4, where a gate electrode of the fourth transistor M4 is coupled to a reset signal output terminal STV0, a first electrode of the fourth transistor M4 is coupled to the pull-up node PU, and a second electrode of the fourth transistor M4 is coupled to a third level signal input terminal VGL;
a fifth transistor M5, where a gate electrode of the fifth transistor M5 is coupled to a second electrode of the ninth transistor M9, a first electrode of the fifth transistor M5 is coupled to a fourth level signal input terminal GCH, and a second electrode of the fifth transistor M5 is coupled to a pull-down node PD;
a sixth transistor M6, where a gate electrode of the sixth transistor M6 is coupled to the pull-up node PU, a first electrode of the sixth transistor M6 is coupled to the pull-down node PD, and a second electrode of the sixth transistor M6 is coupled to the third level signal input terminal VGL;
a seventh transistor M7, where a gate electrode of the seventh transistor M7 is coupled to the reset signal output terminal STV0, a first electrode of the seventh transistor M7 is coupled to the output terminal G_out of the shift register unit to which it belongs, and a second electrode of the seventh transistor M7 is coupled to the third level signal input terminal VGL;
an eighth transistor M8, where a gate electrode of the eighth transistor M8 is coupled to the pull-up node PU, a first electrode of the eighth transistor M8 is coupled to the second electrode of the ninth transistor M9, and a second electrode of the eighth transistor M8 is coupled to the third level signal input terminal VGL;
a ninth transistor M9, where a gate electrode and a first electrode of the ninth transistor M9 are coupled together and connected to a fourth level signal input terminal GCH;
a tenth transistor M10, where a gate electrode of the tenth transistor M10 is coupled to the pull-down node PD, a first electrode of the tenth transistor M10 is coupled to the pull-up node PU, and a second electrode of the tenth transistor M10 is coupled to the third level signal input terminal VGL;
an eleventh transistor M11, where a gate electrode of the eleventh transistor M11 is coupled to the pull-down node PD, a first electrode of the eleventh transistor M11 is coupled to the output terminal G_out of the shift register unit to which it belongs, and a second electrode of the eleventh transistor M11 is coupled to the third level signal input terminal VGL;
a capacitor C1, where a first end of the capacitor C1 is coupled to the pull-up node PU, and a second end of the capacitor C1 is coupled to the output terminal G_out of the shift register unit to which it belongs.

For example, the third transistor M3 includes the transistor structure, but is not limited to it.

In the transistor structure provided in the above embodiments, the non-edge first electrode part includes the main body portion 1011 and at least one protrusion portion 1012, the protrusion portion 1012 is located between the main body portion 1011 and the non-edge second electrode part, so that an intermediate transistor 402 can be formed jointly by the non-edge first electrode part, the non-edge second electrode part, and a control part 301 having an orthographic projection onto the base substrate located between orthographic projections of the non-edge first electrode part and the non-edge second electrode part onto the base substrate. A width of at least part of the protrusion portion 1012 is less than a width of the main body portion 1011, which enables a width of the non-edge first electrode part to be narrowed in a direction close to a channel region of the intermediate sub-transistor 402. In this way, the density of an input current of the intermediate sub-transistor 402 during operation can be effectively reduced, to better balance the overall current density of the transistor structure, thereby effectively overcoming the problem that the intermediate sub-transistor 402 is turned on early due to the characteristic deviation of the transistor structure, and greatly improving the characteristic uniformity of the transistor structure.

Therefore, the gate driving circuit according to the embodiments of the present disclosure can achieve strong driving capability of the gate driving circuit when including the above-mentioned transistor structure, thereby greatly improving the control capability of the gate driving circuit and ensuring the display effect of the display product under the driving of the gate driving circuit.

An embodiment of the present disclosure further provides a display panel, including the gate driving circuit provided in the above embodiments.

It should be noted that the display panel is applied to a display device, which may be any product or component with display functions, such as a television, a display, a digital photo frame, a mobile phone, a tablet, etc. The display device further includes a flexible circuit board, a printed circuit board, and a back plate.

Due to the strong driving capability of the gate driving circuit mentioned above, the control capability of the gate driving circuit is greatly improved. Therefore, when the display panel according to the embodiments of the present disclosure is set to include the gate driving circuit provided in the above embodiments, the display panel display driven by the gate driving circuit can better ensure the display effect of the display panel.

It should be noted that the extension of the signal line along the X direction refers to that the signal line includes a main part and a secondary part connected to the main part, the main part is a line, a line segment or a bar-shaped body, the main part extends along the X direction, and a length of the main part extending along the X direction is greater than a length of the secondary part extending in another direction.

It should be noted that the term “same layer” in the embodiments of the present disclosure refers to film layers located on a same structural layer. Alternatively, for example, film layers on the same layer can be formed using a same film-forming process to form a specific pattern, and then patterned using a same mask through a single patterning process to form a layer structure. Depending on the specific pattern, the single patterning process may include multiple exposures, developments, or etching processes, and the specific pattern in the formed layer structure may be continuous or discontinuous. These specific shapes may also be at different heights or have different thicknesses.

In the embodiments of the method of the present disclosure, the serial number of each step cannot be used to limit an order of each step. For ordinary person in the art, the change in the order of each step shall also fall within the protection scope of the present disclosure without creative effort.

It should be noted that multiple embodiments in this specification are described in a progressive manner, reference can be made to each other for the same and similar parts between multiple embodiments, and each embodiment focuses on the differences from other embodiments. Especially for the method embodiments, the description is relatively simple, because they are basically similar to the product embodiments, and for relevant information, reference can be made to the description in the product embodiments.

Unless otherwise defined, technical or scientific terms used in the present disclosure shall have the usual meanings as understood by persons with general skills in the field to which the present disclosure belongs. Terms “first”, “second” and the like in the present disclosure do not indicate any order, quantity, or importance, but are only used to distinguish different components. Word “include”, “include” or the like refer to that an element or an object that appears before the word includes elements, or objects, or equivalents thereof listed after the word, and does not exclude other elements or objects. The term such as “connect”, “couple”, or “interconnect” is not limited to physical or mechanical connection, and can include electrical connection, whether direct or indirect connection. Terms such as “on”, “under”, “left”, “right” are only used to represent a relative positional relationship, and the relative positional relationship may also change accordingly when the absolute position of the described object changes.

It is appreciated that when an element such as a layer, a film, a region, or a substrate is referred to as being located “on” or “under” another element, the element may be “directly” located “on” or “under” the other element, or there may be an intermediate element.

In the description of the above embodiments, specific features, structures, materials, or characteristics may be combined in any one or more embodiments or examples in a suitable manner. The above embodiments are only specific implementations of the present disclosure, and the protection scope of the present disclosure is not limited thereto. Any skilled person in the art can easily think of changes or replacements within the technical scope disclosed in the present disclosure, which shall fall within the protection scope of the present disclosure. Therefore, the protection scope of the present disclosure should be subjected to the protection scope of the claims.

1. A transistor structure, comprising: at least one transistor group arranged along a width direction of a channel, wherein the at least one transistor group comprises: at least two control parts, at least two first electrode parts and at least two second electrode parts; the second electrode part and the first electrode part are alternately arranged along a length direction of the channel, and an orthographic projection of the control part onto a base substrate of the transistor structure is located between orthographic projections of one of the second electrode parts and one of the first electrode parts that are adjacent to each other onto the base substrate;
the at least two first electrode parts include a non-edge first electrode part, the non-edge first electrode part is located between two adjacent second electrode parts, the two adjacent second electrode parts include at least one non-edge second electrode part, and the non-edge second electrode part is located between two adjacent first electrode parts;
the non-edge first electrode part comprises a main body portion and at least one protrusion portion, wherein the protrusion portion is located between the main body portion and the non-edge second electrode part, and along the width direction of the channel, a width of at least part of the protrusion portion is less than a width of the main body portion.

2. The transistor structure according to claim 1, wherein the transistor group comprises an active pattern, and an overlapping region is formed between an orthographic projection of the active pattern onto the base substrate and an orthographic projection of each of the at least two control parts onto the base substrate; and along the width direction of the channel, the width of at least part of the protrusion portion is less than a width of the overlapping region.

3. The transistor structure according to claim 2, wherein along the width direction of the channel, the width of the main body portion is greater than or equal to the width of the overlapping region.

4. The transistor structure according to claim 2, wherein the non-edge first electrode part comprises at least two protrusion portions, a part of the protrusion portions is located on a first side of the main body portion, and another part of the protrusion portions is located on a second side of the main body portion, wherein the first side and the second side are opposite to each other along the length direction of the channel.

5. The transistor structure according to claim 2, wherein at least two protrusion portions arranged along the width direction of the channel are arranged on a same side of the main body portion, and the sum of minimum widths of the at least two protrusion portions along the width direction of the channel is less than the width of the overlapping region.

6. The transistor structure according to claim 2, wherein the transistor structure comprises at least two transistor groups arranged along the width direction of the channel, in adjacent transistor groups, main body portions adjacent to each other along the width direction of the channel are coupled through a first connection part, and along the length direction of the channel, a width of the first connection part is greater than or equal to the width of the main body portion.

7. The transistor structure according to claim 6, wherein along the length direction of the channel, the width of the first connection part is greater than or equal to the sum of the width of the main body portion and the width of the protrusion portion.

8. The transistor structure according to claim 2, wherein the protrusion portion comprises at least two sub-portions arranged in sequence along the length direction of the channel, and widths of adjacent sub-portions along the width direction of the channel are different from each other; and at least one sub-portion of the at least two sub-portions has a width along the width direction of the channel that is less than the width of the overlapping region.

9. The transistor structure according to claim 8, wherein the at least two sub-portions include at least one first sub-portion, the first sub-portion has a first width along the width direction of the channel, and the first width gradually increases or decreases in a direction away from the main body portion.

10. The transistor structure according to claim 9, wherein the at least two sub-portions include at least one second sub-portion, the second sub-portion has a second width along the width direction of the channel, the second width is equal to a minimum value of the first width, and the second sub-portion is coupled to one end of the first sub-portion having the minimum value of the first width.

11. The transistor structure according to claim 10, wherein the at least two sub-portions include a first sub-portion and a second sub-portion; the first sub-portion is located between the second sub-portion and the main body portion, or the second sub-portion is located between the first sub-portion and the main body portion.

12. The transistor structure according to claim 9, wherein a maximum value of the first width is less than or equal to the width of the overlapping region.

13. The transistor structure according to claim 8, wherein the at least two sub-portions include a third sub-portion, a fourth sub-portion and a fifth sub-portion arranged in sequence along the length direction of the channel; along the width direction of the channel, a width of the third sub-portion and a width of the fifth sub-portion are both greater than a width of the fourth sub-portion, and the width of the fourth sub-portion is less than the width of the overlapping region.

14. The transistor structure according to claim 13, wherein the width of the third sub-portion along the width direction of the channel is less than or equal to the width of the overlapping region; and/or, the width of the fifth sub-portion along the width direction of the channel is less than or equal to the width of the overlapping region.

15. The transistor structure according to claim 13, wherein the width of the third sub-portion is equal to the width of the fifth sub-portion along the width direction of the channel.

16. The transistor structure according to claim 13, wherein the fourth sub-portion comprises at least two sub-patterns arranged at intervals along the width direction of the channel, and the sum of widths of the at least two sub-patterns along the width direction of the channel is less than the width of the overlapping region.

17. The transistor structure according to claim 6, wherein the transistor structure comprises at least two transistor groups arranged along the width direction of the channel; in adjacent transistor groups, second electrode parts that are adjacent along the width direction of the channel are coupled to each other through a second connection part, and control parts that are adjacent along the width direction of the channel are coupled to each other through a third connection part; and
along the width direction of the channel, on one side of the at least two transistor groups, the at least two second electrode parts are coupled to each other, on the other side of the at least two transistor groups, the at least two first electrode parts are coupled to each other, and the at least two control parts are coupled to each other,
wherein the control part comprises bottom gate patterns and top gate patterns, and the bottom gate patterns, the active pattern and the top gate patterns are arranged in sequence along a direction away from the base substrate; and
along the width direction of the channel, adjacent bottom gate patterns are coupled to each other through a bottom gate connection part, and adjacent top gate patterns are coupled to each other through a top gate connection part.

18. (canceled)

19. The transistor structure according to claim 1, wherein the at least two first electrode parts include an edge first electrode part, and the edge first electrode part is located at an outermost edge of the transistor structure along the length direction of the channel; and
the edge first electrode part comprises an edge main body portion and at least one edge protrusion portion, wherein the edge protrusion portion is located between the edge main body portion and the non-edge second electrode part, and along the width direction of the channel, a width of at least part of the edge protrusion portion is less than a width of the edge main body portion.

20. A gate driving circuit, comprising a shift register unit, wherein the shift register unit comprises the transistor structure according to claim 1.

21. A display panel, comprising the gate driving circuit according to claim 20.
